(19) United States
(12) Patent Application Publication
(10) Pub. No.: US 2023/0406243 A1
(43) Pub. Date: Dec. 21, 2023

(54) ELECTROMAGNETIC COMPATIBILITY (EMC) SHIELDED VEHICLE ELECTRICAL MODULES

(71) Applicant: FORD GLOBAL TECHNOLOGIES, LLC, Dearborn, MI (US)

(72) Inventors: Mohammed Michael Baydoun, Dearborn Heights, MI (US); Leena Shah, Rochester Hills, MI (US); Robert Vitali, Sterling Heights, MI (US)

(21) Appl. No.: 17/844,332

(22) Filed: Jun. 20, 2022

(51) Int. Cl. B60R 16/023; H02G 3/08; H05K 9/00

(52) U.S. Cl. CPC B60R 16/023; H02G 3/08; H05K 9/0045; H05K 9/0047

(57) ABSTRACT

Electrical module designs are disclosed for motor vehicles. An exemplary electrical module (e.g., a junction box, etc.) may include a polymer-based housing assembly and an EMC shield that is adapted to influence an electromagnetic compatibility of the polymer-based housing assembly. The EMC shield may include a metallic foil, a metallic filler, a metallic coating, or combinations thereof.

### TECHNICAL FIELD

This disclosure relates generally to vehicle electrical modules, and more particularly to vehicle electrical housings that include features for increasing the electromagnetic compatibility (EMC) of the electrical modules.

### BACKGROUND

Modern day motor vehicles are equipped with a plurality of electrical modules that support a variety of electrical functions of the vehicles. One example of such an electrical module is a high voltage junction box. Metallic-based housings of electrical modules provide a conductive path for directing electromagnetic radiation to ground, thereby substantially mitigating the potential for electromagnetic interference. However, polymer-based housings of electrical modules are generally non-conductive and therefore can cause electromagnetic compatibility (EMC) issues within the vehicle environment.

### SUMMARY

A vehicle electrical module according to an exemplary aspect of the present disclosure includes, among other things, a housing assembly including a polymer-based substrate, and an electromagnetic compatibility (EMC) shield adapted to influence an electromagnetic compatibility (EMC) of the polymer-based substrate.

In a further non-limiting embodiment of the foregoing vehicle electrical module, the vehicle electrical module is a high voltage junction box.

In a further non-limiting embodiment of either of the foregoing vehicle electrical modules, the polymer-based substrate and the EMC shield together establish a wall of the housing assembly.

In a further non-limiting embodiment of any of the foregoing vehicle electrical modules, the wall is part of a cover of the housing assembly.

In a further non-limiting embodiment of any of the foregoing vehicle electrical modules, the wall is part of a base of the housing assembly.

In a further non-limiting embodiment of any of the foregoing vehicle electrical modules, the wall is an interior facing wall of the housing assembly.

In a further non-limiting embodiment of any of the foregoing vehicle electrical modules, the EMC shield includes a metallic foil that is secured to the polymer-based substrate.

In a further non-limiting embodiment of any of the foregoing vehicle electrical modules, the EMC shield includes a metallic filler provided within the polymer-based substrate.

In a further non-limiting embodiment of any of the foregoing vehicle electrical modules, the EMC shield includes a metallic foil that is secured to the polymer-based substrate and a metallic filler provided within the polymer-based substrate.

In a further non-limiting embodiment of any of the foregoing vehicle electrical modules, the EMC shield includes a metallic coating applied to the polymer-based substrate.

In a further non-limiting embodiment of any of the foregoing vehicle electrical modules, the metallic coating includes a metallic paint.

In a further non-limiting embodiment of any of the foregoing vehicle electrical modules, the EMC shield includes a metallic coating applied to the polymer-based substrate and a metallic foil positioned over the metallic coating.

In a further non-limiting embodiment of any of the foregoing vehicle electrical modules, the EMC shield includes a metallic filler provided within the polymer-based substrate and a metallic coating applied to the polymer-based substrate.

In a further non-limiting embodiment of any of the foregoing vehicle electrical modules, an electronic is housed within an interior of the housing assembly.

A motor vehicle according to another exemplary aspect of the present disclosure includes, among other things, an electrical module including a first polymer-based housing section, a second polymer-based housing section, an electronic housed within an interior established by the first and second polymer-based housing sections, and an electromagnetic compatibility (EMC) shield adapted to increase an electromagnetic compatibility (EMC) of the electrical module.

In a further non-limiting embodiment of the foregoing motor vehicle, the electrical module is a high voltage junction box.

In a further non-limiting embodiment of either of the foregoing motor vehicles, the EMC shield includes a metallic foil.

In a further non-limiting embodiment of any of the foregoing motor vehicles, the EMC shield includes a metallic filler or a metallic coating.

In a further non-limiting embodiment of any of the foregoing motor vehicles, the EMC shield includes a metallic foil and either a metallic filler or a metallic coating.

In a further non-limiting embodiment of any of the foregoing motor vehicles, the electronic is a relay, a fuse, or a bus bar.

The embodiments, examples and alternatives of the preceding paragraphs, the claims, or the following description and drawings, including any of their various aspects or respective individual features, may be taken independently or in any combination. Features described in connection with one embodiment are applicable to all embodiments, unless such features are incompatible.

The various features and advantages of this disclosure will become apparent to those skilled in the art from the following detailed description. The drawings that accompany the detailed description can be briefly described as follows.

### BRIEF DESCRIPTION OF THE DRAWINGS

FIG. 1 schematically illustrates a motor vehicle equipped with an electrical module.

FIG. 2 illustrates an exemplary vehicle electrical module.

FIG. 3 is a top view of select portions of the vehicle electrical module of FIG. 2.

FIG. 4 illustrates an exemplary electromagnetic compatibility shield provided on a housing part of a vehicle electrical module.

FIG. 5 illustrates another exemplary electromagnetic compatibility shield provided on a housing part of a vehicle electrical module.

FIG. 6 illustrates another exemplary electromagnetic compatibility shield provided on a housing part of a vehicle electrical module.

FIG. 7 illustrates another exemplary electromagnetic compatibility shield provided on a housing part of a vehicle electrical module.

FIG. 8 illustrates another exemplary electromagnetic compatibility shield provided on a housing part of a vehicle electrical module.

FIG. 9 illustrates yet another exemplary electromagnetic compatibility shield provided on a housing part of a vehicle electrical module.

### DETAILED DESCRIPTION

This disclosure details exemplary electrical module designs for motor vehicles. An exemplary electrical module (e.g., a junction box, etc.) may include a polymer-based housing assembly and an EMC shield that is adapted to influence an electromagnetic compatibility of the polymer-based housing assembly. The EMC shield may include a metallic foil, a metallic filler, a metallic coating, or combinations thereof. These and other features are discussed in greater detail in the following paragraphs of this detailed description.

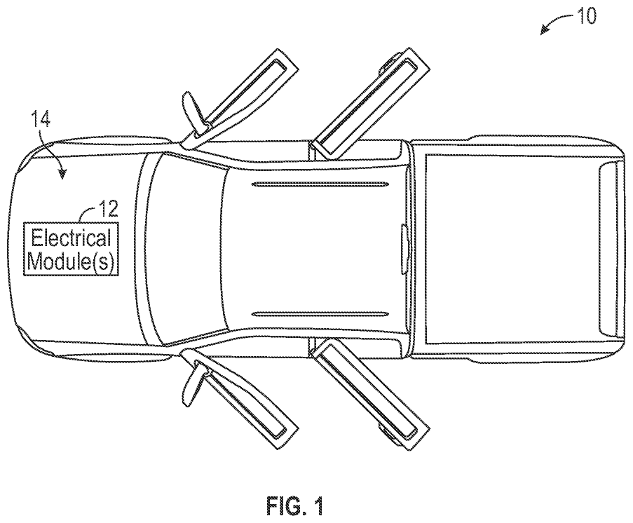

FIG. 1 schematically illustrates a motor vehicle 10. The vehicle 10 may be a car, a pickup truck, a van, a sport utility vehicle, or any other type of vehicle. The vehicle 10 could also be a conventional internal combustion engine powered motor vehicle, a high voltage battery powered hybrid or electric vehicle, or an autonomous vehicle (i.e., a driverless vehicle).

The vehicle 10 may include one or more electrical modules 12. For simplicity, only one electrical module 12 is depicted in FIG. 1. However, the vehicle 10 could include a plurality of electrical modules for supporting a multitude of electrical functions within the vehicle 10. A junction box is an example of a vehicle electrical module that is capable of distributing electrical power to a plurality of electrical devices of the vehicle 10.

Although a specific component relationship is illustrated in the figures of this disclosure, the illustrations are not intended to limit this disclosure. The placement and orientation of the various components of the vehicle 10 are shown schematically and could vary within the scope of this disclosure. For example, although schematically depicted in FIG. 1 as being located within a front end assembly 14 of the vehicle 10, the electrical module 12 could be mounted at any vehicle location, including vehicle underbody locations. In addition, the various figures accompanying this disclosure are not necessarily drawn to scale, and some features may be exaggerated or minimized to emphasize certain details of a particular component or system.

Many vehicle electrical module have traditionally included metallic-based housings. However, metallic materials tend to increase the weight of the vehicle and may be susceptible to corrosion. There is thus a desire to utilize polymer-based housings within the electrical modules. However, polymer-based housings are generally non-conductive and therefore may cause electromagnetic compatibility (EMC) issues within the vehicle environment. This disclosure is therefore directed to vehicle electrical module designs that include features for increasing the electromagnetic compatibility of the electrical modules.

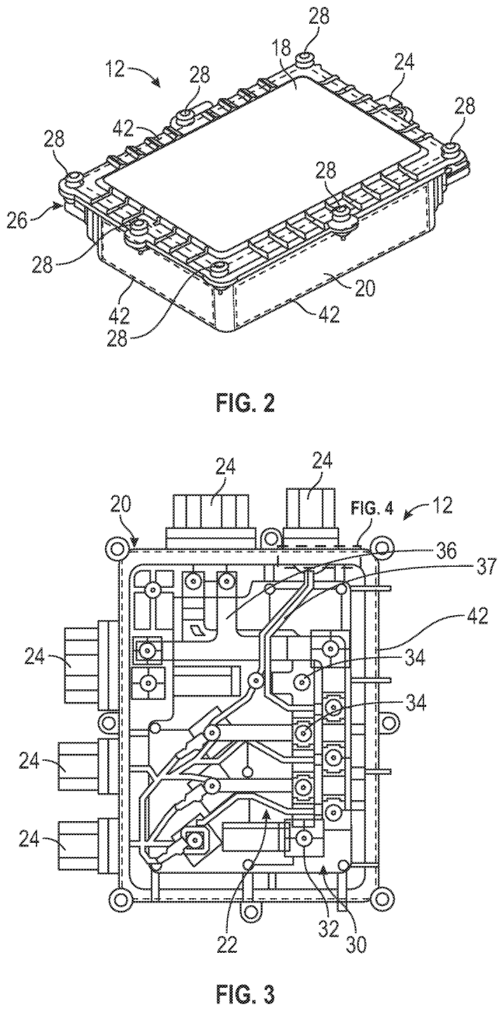

FIGS. 2 and 3 illustrate an electrical module 12 that may be employed within a vehicle, such as the vehicle 10 of FIG. 1. In an embodiment, the electrical module 12 is a high voltage junction box of the vehicle 10. However, the electrical module 12 could be any vehicle electrical module that is susceptible to electromagnetic interference (EMI).

The electrical module 12 may include a first housing section 18 (e.g., a cover), a second housing section 20 (e.g., a base), various electronics 22, and one or more connectors 24. The first housing section 18 may be removably secured to the second housing section 20 to establish a housing assembly 26 of the electrical module 12. One or more fasteners 28 (e.g. bolts, screws, etc.) may be used to secure the first housing section 18 and the second housing section 20 together.

In an embodiment, the housing assembly 26 is a sealed enclosure. The housing assembly 26 of the electrical module 12 may include any size, shape, and configuration and is therefore not limited to the exact configuration shown in FIGS. 2-3.

The housing assembly 26 of the electrical module 12 may establish an interior 30 for housing the electronics 22. The electronics 22 may include components such as relays 32, fuses 34, bus bars 36, wiring 37, etc. However, other types of electronics 22 could alternatively or additionally be housed within the interior 30.

The connectors 24 may be mounted to portions of the housing assembly 26. In an embodiment, each connector 24 is mounted to the second housing section 20, and the connectors 24 may be mounted at multiple sides of the second housing section 20 (best shown in FIG. 3). However, other implementations are further contemplated within the scope of this disclosure. Each connector 24 may establish a connection point for connecting a cable of an electrical device of the vehicle 10, for example.

The housing assembly 26, including both the first housing section 18 and the second housing section 20, may be made of one or more polymer-based materials. Exemplary polymer-based materials include, but are not limited to, polyethylene, polypropylene, polystyrene, polyethylene, sheet moulding compounds (e.g., glass-fiber reinforced polyester), polyamine, and polyamide (e.g., nylon), and combinations thereof.

Due to its polymeric makeup, the housing assembly 26 may include features for increasing the EMC of the electrical module 12. For example, the housing assembly 26 may include an EMC shield 42 designed to shield the electronics 22 located inside the electrical module 12 from electromagnetic interferences that can originate from electronics located near the electrical module 12 and vice versa, thereby improving the EMC of the electrical module 12.

The EMC shield 42 may be provided on the first housing section 18, the second housing section 20, or both. Moreover, the EMC shield 42 may be provided on select portions of the first housing section 18 and/or the second housing section 20 or on entire surfaces of the first housing section 18 and/or the second housing section 20.

In an embodiment, the EMC shield 42 is provided on all interior facing surfaces of the first housing section 18 and the second housing section 20. The interior facing surfaces include any surface that faces toward the electronics 22 housed within the interior 30. However, the EMC shield 42 could alternatively or additionally be provided on exterior facing surfaces of the first housing section 18 and the second housing section 20. The EMC shield 42 may create a blanket or shell about the electronics 22 that matches the design of the housing assembly 26 to provide the EMC.

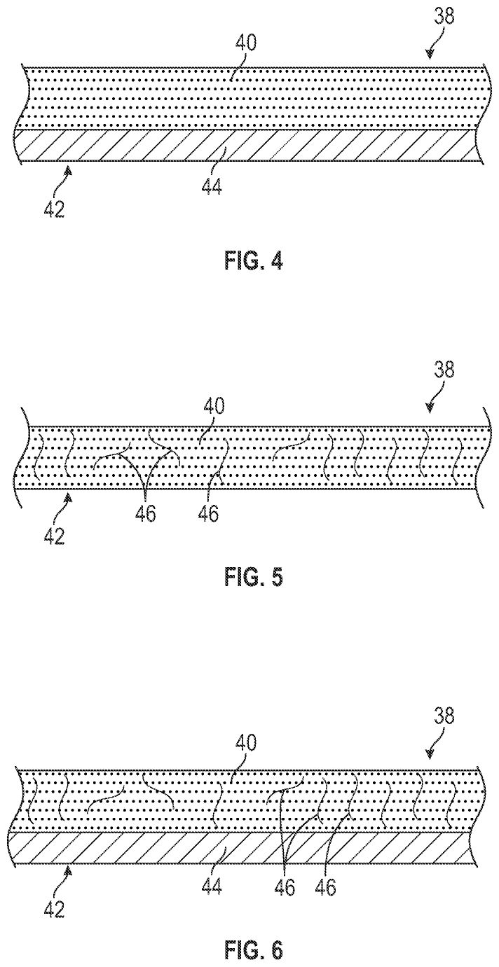

FIG. 4, with continued reference to FIGS. 2-3, illustrates select portions of a wall 38 of the housing assembly 26 of the electrical module 12. The wall 38 may be part of the first housing section 18 or may be part of the second housing section 20 of the housing assembly 26.

In an embodiment, the wall 38 is an interior facing wall of the housing assembly 26. The wall 38 thus faces inwardly toward the electronics 22 housed within the interior 30.

The wall 38 may include a polymer-based substrate 40 and a metallic foil 44, which may be a relatively thin sheet of metallic material. The metallic foil 44 may be embedded within or otherwise secured to the polymer-based substrate 40 to stablish the EMC shield 42. The metallic foil 44 can establish a conductive path within the wall 38. The metallic foil 44 is electrically and magnetically conductive and is therefore adapted to provide the electrical module 12 with electromagnetic radiation shielding properties.

The metallic foil 44 may be made of any suitable metallic materials. Exemplary metallic materials include, but are not limited to, aluminum, steel, and copper.

In another embodiment, shown in FIG. 5, the EMC shield 42 may be established by a metallic filler 46 provided within the polymer-based substrate 40 of the wall 38. The metallic filler 46 may be mixed into the resin of the polymer-based substrate 40 prior to using the resin to manufacture the first housing section 18 or second housing section 20. In another embodiment, the EMC shield 42 may be established by both the metallic foil 44 and the metallic filler 46 (see, e.g., FIG. 6).

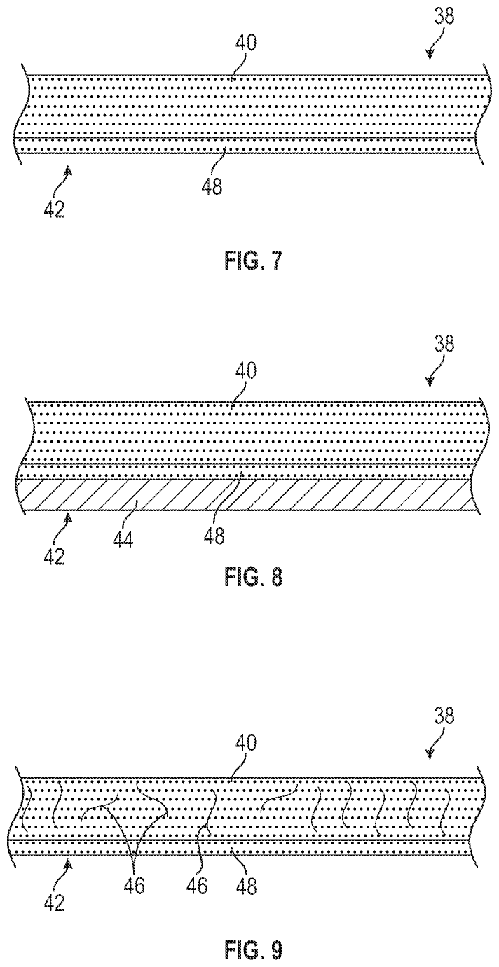

In another embodiment, shown in FIG. 7, the EMC shield 42 may be established by a metallic coating 48 applied to the polymer-based substrate 40 of the wall 38. The metallic coating 48 may be brushed or sprayed onto the wall 38, for example. The metallic coating 48 may be a metallic paint, such as an aluminum powder paint. However, other types of metallic coatings 48 could also be suitable for this purpose.

In another embodiment, the EMC shield 42 may be established by both the metallic foil 44 and the metallic coating 48 (see, e.g., FIG. 8). In yet another embodiment, the EMC shield 42 may be established by both the metallic filler 46 and the metallic coating 48 (see, e.g., FIG. 9).

The configurations of the wall 38 shown in FIGS. 4, 5, 6, 7, 8, and 9 can be utilized in select, discrete sections of the housing assembly 26 or could be applied over an entirety of one or more walls of the housing assembly 26. In addition, the configurations of FIGS. 4, 5, 6, 7, 8, and 9 are not shown to scale and have been exaggerated to better illustrate various features of this disclosure.

The vehicle electrical modules of this disclosure include a polymer-based housing equipped with an EMC shield. The shield is capable of providing electromagnetic radiation shielding properties. The proposed designs are as effective as metallic-based housings in terms of providing EMC while also providing reduced weight, increased serviceability, and reduced manufacturing expenses.

Although the different non-limiting embodiments are illustrated as having specific components or steps, the embodiments of this disclosure are not limited to those particular combinations. It is possible to use some of the components or features from any of the non-limiting embodiments in combination with features or components from any of the other non-limiting embodiments.

It should be understood that like reference numerals identify corresponding or similar elements throughout the several drawings. It should be understood that although a particular component arrangement is disclosed and illustrated in these exemplary embodiments, other arrangements could also benefit from the teachings of this disclosure.

The foregoing description shall be interpreted as illustrative and not in any limiting sense. A worker of ordinary skill in the art would understand that certain modifications could come within the scope of this disclosure. For these reasons, the following claims should be studied to determine the true scope and content of this disclosure.

1. A vehicle electrical module, comprising:
a housing assembly including a polymer-based substrate and an electromagnetic compatibility (EMC) shield adapted to influence an electromagnetic compatibility (EMC) of the polymer-based substrate,
wherein the vehicle electrical module is a high voltage junction box.

2. (canceled)

3. The vehicle electrical module as recited in claim 1, wherein, together, the polymer-based substrate and the EMC shield establish a wall of the housing assembly.

4. The vehicle electrical module as recited in claim 3, wherein the wall is part of a cover of the housing assembly.

5. The vehicle electrical module as recited in claim 3, wherein the wall is part of a base of the housing assembly.

6. The vehicle electrical module as recited in claim 3, wherein the wall is an interior facing wall of the housing assembly.

7. The vehicle electrical module as recited in claim 1, wherein the EMC shield includes a metallic foil that is secured to the polymer-based substrate.

8. The vehicle electrical module as recited in claim 1, wherein the EMC shield includes a metallic filler provided within the polymer-based substrate.

9. The vehicle electrical module as recited in claim 1, wherein the EMC shield includes a metallic foil that is secured to the polymer-based substrate and a metallic filler provided within the polymer-based substrate.

10. The vehicle electrical module as recited in claim 1, wherein the EMC shield includes a metallic coating applied to the polymer-based substrate.

11. The vehicle electrical module as recited in claim 10, wherein the metallic coating includes an aluminum powder paint.

12. The vehicle electrical module as recited in claim 1, wherein the EMC shield includes a metallic coating applied to the polymer-based substrate and a metallic foil positioned over the metallic coating.

13. The vehicle electrical module as recited in claim 1, wherein the EMC shield includes a metallic filler provided within the polymer-based substrate and a metallic coating applied to the polymer-based substrate.

14. The vehicle electrical module as recited in claim 1, comprising an electronic housed within an interior of the housing assembly.

15. A motor vehicle, comprising:
an electrical module including:
a first polymer-based housing section;
a second polymer-based housing section;
an electronic housed within an interior established by the first and second polymer-based housing sections; and
an electromagnetic compatibility (EMC) shield adapted to increase an electromagnetic compatibility (EMC) of the electrical module,
wherein the electrical module is a high voltage junction box.

16. (canceled)

17. The motor vehicle as recited in claim 15, wherein the EMC shield includes a metallic foil.

18. The motor vehicle as recited in claim 15, wherein the EMC shield includes a metallic filler or a metallic coating.

19. The motor vehicle as recited in claim 15, wherein the EMC shield includes a metallic foil and either a metallic filler or a metallic coating.

20. The motor vehicle as recited in claim 15, wherein the electronic is a relay, a fuse, or a bus bar.

21. A motor vehicle, comprising:
an electrical device;
a high voltage junction box configured to distribute electrical power to the electrical device, wherein the high voltage junction box includes:
a first polymer-based housing section;
a second polymer-based housing section;
an electronic housed within an interior established by the first and second polymer-based housing sections; and
an electromagnetic compatibility (EMC) shield adapted to increase an electromagnetic compatibility (EMC) of the high voltage junction box,
wherein the EMC shield includes a metallic foil that is secured to a polymer-based substrate of the first polymer-based housing section for the second polymer-based housing section, and a metallic filler provided within a resin of the polymer-based substrate.

22. The motor vehicle as recited in claim 21, wherein the high voltage junction box includes a connector mounted to the first polymer-based housing section or the second polymer-based housing section, the connector establishing a connection point for connecting a cable of the electrical device to the high voltage junction box.
